(19) United States
(12) Patent Application Publication
(10) Pub. No.: US 2012/0276714 A1
(43) Pub. Date: Nov. 1, 2012

(54) METHOD OF OXIDIZING POLYSILAZANE

(75) Inventors: Shing-Yih Shih, Taoyuan County (TW); Yi-Nan Chen, Taoyuan County (TW); Hsien-Wen Liu, Taoyuan County (TW)

(73) Assignee: NANYA TECHNOLOGY CORPORATION, TAOYUAN (TW)

(21) Appl. No.: 13/096,976

(22) Filed: Apr. 28, 2011

(51) Int. Cl. H01L 21/31

(52) U.S. Cl. 438/435; 438/761; 257/E21.24

(57) ABSTRACT

A method of oxidizing polysilazane is disclosed, comprising providing a substrate, comprising a trench, forming a polysilazane layer in the trench, and treating the polysilazane layer in an acid containing solution applied with mega-sonic waves to oxidize the polysilazane layer, wherein the acid containing solution comprises phosphoric acid, sulfuric acid, H₂SO₄ added with O₃ (SOM), H₂SO₄ added with H₂O₂ (SPM), H₃PO₄ added with O₃, or H₃PO₄ added with H₂O₂, and removing the silicon oxide layer outside of the trench.

### BACKGROUND OF THE INVENTION

1. Field of the Invention

The invention relates generally to semiconductor processing methods of forming and utilizing insulative materials for electrical isolation in integrated circuits, and more particularly to processes for oxidizing polysilazane coatings.

2. Description of the Related Art

In the fabrication of semiconductor integrated circuits, semiconductor elements are integrated and laid out within a small area on a chip requiring the devices to be placed in close proximity to each other. With the continuing decrease in the dimensions and spacing of devices on integrated circuits (ICs), insulative materials are being deposited to electrically isolate the various active components such as transistors, resistors and capacitors. Isolation insulative materials are typically made of silicon dioxide (SiO₂).

For example, interlayer dielectric (ILD) or pre-metal dielectric (PMD) layers isolate structures from metal interconnect layers, which may require filling narrow gaps having high aspect ratios (ratio of depth to width) of five or greater. Insulative structures such as shallow trench isolation (STI) regions are also formed in recesses (trenches) within the substrate between components. Such trenches can have a width as narrow as 0.01 to 0.05 microns or smaller, and filling such narrow features can be difficult. In addition, the dielectric material must be able to withstand subsequent processing steps such as etching and cleaning steps.

Dielectric materials are typically deposited by chemical vapor deposition (CVD) or plasma enhanced chemical vapor deposition (PECVD). For example, in a typical STI method, a trench is etched into a silicon substrate, and the trench is filled by CVD of an oxide such as silicon dioxide as a conformal layer. In the trenches, the conformal layers of oxide are initially formed on the sidewalls and grow in size outward into the center of the trenches to where the oxide layers meet. With high aspect ratio features, the width becomes narrower while the depth becomes much greater; thus, it is difficult to form a void-free or seam-free gap fill using standard CVD or PECVD techniques.

Flowable materials such as spin-on dielectrics (SODs), spin-on glasses (SOGs), and spin-on polymers such as silicates, siloxanes, silazanes or silisesquioxanes, have been developed, which generally have good gap filling properties. A silicon oxide film is formed by spin-coating a liquid solution of the silicon-containing polymer onto a surface of a substrate, baking the material to remove the solvent, and then thermally oxidizing the polymer layer in an oxygen, or steam, and atmosphere at an elevated temperature of up to about 100° C. A drawback of the current methods is illustrated in accordance with FIG. 1. Referring to FIG. 1, O₂ and H₂O are driven into a polysilazane coating layer 106 when performing an oxidization and densification process to the polysilazane coating layer 106. In the current methods, due to the high temperature process, a silicon nitride liner layer 104 with a relatively thick thickness (more than 6 nm) is required to prevent oxidizing the substrate 102. However, this silicon nitride liner layer 104 limits the application of STI gap fill, if the trench width shrinks to be below 30 nm node. Another drawback is that the high temperature treatments can degrade other structures such as aluminum or other metal wiring layers that have a low thermal tolerance. Such products may require limited thermal budget processing where extensive densification can hurt device parameters. Consequently, lower temperature processing techniques are desired.

### BRIEF SUMMARY OF INVENTION

The invention provides a method of oxidizing polysilazane, comprising providing a substrate, comprising a trench, forming a polysilazane layer in the trench, and treating the polysilazane layer in an acid containing solution applied with mega-sonic waves to oxidize the polysilazane layer.

The invention further provides a method of forming a trench isolation structure, comprising providing a substrate, forming a trench in the substrate, forming a polysilazane layer in the trench, treating the polysilazane layer in an acid containing solution applied with mega-sonic waves at a temperature of between 100° C. to 300° C. to convert the polysilazane layer into a silicon oxide layer, wherein the acid containing solution comprises phosphoric acid, sulfuric acid, H₂SO₄ added with O₃ (SOM), H₂SO₄ added with H₂O₂ (SPM), H₃PO₄ added with O₃, or H₃PO₄ added with H₂O₂, and removing the silicon oxide layer outside of the trench.

### BRIEF DESCRIPTION OF DRAWINGS

The invention can be more fully understood by reading the subsequent detailed description and examples with references made to the accompanying drawings, wherein,

FIG. 1 shows a conventional method for forming a trench isolation structure.

FIGS. 2A-2E illustrate a method for forming a dielectric layer according to one embodiment of the present invention, when forming a shallow trench isolation (STI) structure.

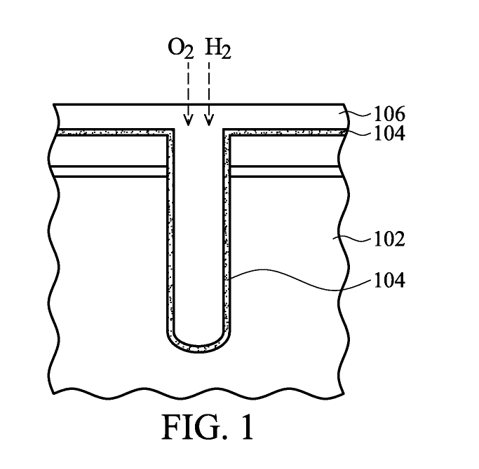

### DETAILED DESCRIPTION OF INVENTION

It is understood that specific embodiments are provided as examples to teach the broader inventive concept, and one of ordinary skill in the art can easily apply the teaching of the present disclosure to other methods or apparatus. The following discussion is only used to illustrate the invention, not limit the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

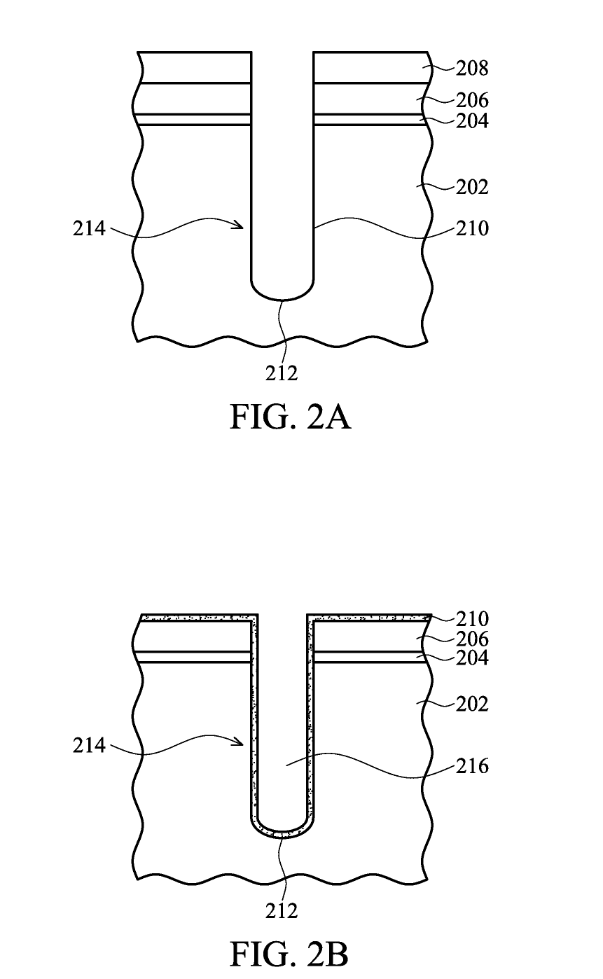

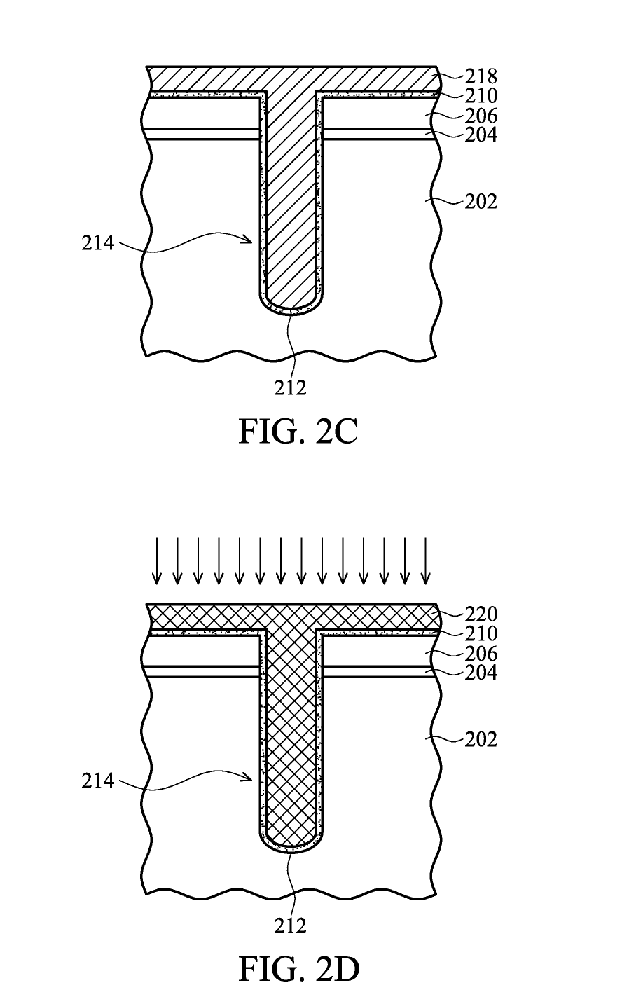

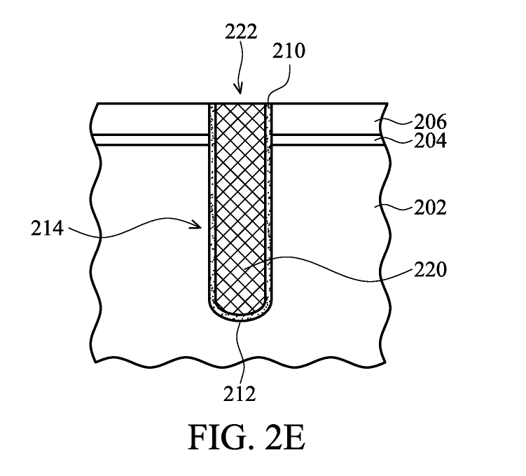

FIGS. 2A-2E illustrate a method for forming a dielectric layer according to one embodiment of the present invention, when forming a shallow trench isolation (STI) structure, which may be employed for electrically isolating devices in an integrated circuit from one another. By way of example, the STI structure can be formed relative to transistor gate constructions and adjacent transistor source/drain regions in the substrate.

Referring to FIG. 2A, a wafer fragment is shown at a preliminary processing step. The wafer fragment in progress can comprise a semiconductor wafer substrate 202 or the wafer along with various process layers formed thereon, including one or more semiconductor layers or other formations, and active or operable portions of semiconductor devices. A semiconductor device can comprise a transistor, capacitor, electrode, insulator or any of a variety of components commonly utilized in semiconductor structures.

The wafer fragment is shown as comprising a semiconductor substrate 202 having a thin first pad layer 204 (SiO₂) of about 8-20 nm formed thereon, which serves as a pad oxide. First, a pad layer 204 can be formed, for example, by thermal oxidation of the substrate 202, by CVD deposition, sputtering, and the like. Optionally, a thicker second pad layer 206, preferably a silicon nitride (Si₃N₄) layer having a thickness of about 40-200 nm, can be formed over the first pad layer 204 by a CVD or other deposition technique, to provide oxidation and a CMP hard mask layer. A photoresist mask layer 208 is applied and patterned using a lithographic patterning technique, and the first pad layer 204, second pad layer 206, and substrate 202 are etched to form an opening or recess such a shallow trench 214 in the substrate 202 for device isolation. For example, the trench 214 can have a width of about 0.1 μm and a depth of about 0.5 μm, with an aspect ratio of 5 (=0.5/0.1). The trench 214 includes sidewalls 210 and a bottom surface 212. The trench 214 can have sloped or tapered sidewalls 210 or vertical sidewalls 210 formed by an anisotropic etching process. The photoresist mask layer 208 is then removed to form a trenched structure, as shown in FIG. 2B.

After stripping the photoresist mask layer 208 and cleaning the trenched structure, as shown in FIG. 2B, a thin silicon nitride liner layer 216 can then be formed on the sidewalls 210 and bottom surface 212 of the trench 214, for example, by thermal nitridation or high density plasma CVD using SiH₄ and NH₃ as source gases. The silicon nitride liner layer 216 is about 5 nm to about 10 nm thick. It is noted that since the method of oxidizing polysilazane uses a process temperature of less than conventional method, the silicon nitride liner layer 216 can be thinner than prior art silicon nitride liner layers, such that polysilazane can be used in the application of the STI gap-fill when the trench 214 width shrinks to be below 30 nm node. In another embodiment of the invention, the silicon nitride liner layer 216 is not required.

As shown in FIG. 2C, a spin-on silicon-containing polymer solution is coated on the substrate 202 and into the trench 214 to form a polysilazane coating layer 218. Typically, the polysilazane coating layer 218 is formed on the substrate 202 by spin coating or a “spin-on-glass (SOG)” process, although other methods such as flow coating, dipping or spraying can be used.

In a preferred embodiment, the polysilazane coating layer 218 is deposited as a coating from a polysilazane solution in an organic solvent by a spin coating process (or SOG process) to fill a predetermined portion or the entire trench 214. Polysilazanes contain SiₓN_{y}H_{z} type units in which the Si atoms are in a “reducing environment” in —Si—NH— bonds. Polysilazane material cannot be etched or processed satisfactorily without modification, wherein a 500:1 HF will not be uniformly etched with a greater than 1000 Å/minute etch rate. Oxidation of N bonds is required to transform the material to SiO₂.

In forming a layer on the substrate 202, a solution of polysilazane is dropped onto a surface of a silicon substrate or layer on the substrate 202 while rotating the substrate 202 on a horizontal plane to form a uniformly-coated film of the solution on the entire surface of the substrate 202 or layer due to the centripetal force applied to the substrate 202 (e.g. wafer). The thickness of the polysilazane coating layer 218 can be controlled by means of the concentration of the coating solution and the speed of rotation of the substrate 202. The coating layer generally ranges in thickness from about 30 nm to about 500 nm.

The conditions under which the polysilazane solution is spin-coated onto the surface of the substrate 202 include a substrate 202 temperature of about 18° C., to about 30° C., and a typical spin rotation of about 500 rpm to about 6,000 rpm for a rotation time of about 2 seconds.

As depicted in FIG. 2D, after coating, the substrate 202 is heated in an acid containing solution applied with mega-sonic waves to oxidize the polysilazane coating layer 218 by removing the organic solvent and producing a silicon oxidize layer 220. In this step, the polysilazane coating layer is subjected to a wet oxidation chemistry to oxidize the polysilazane groups SiₓN_{y}H_{z} of the polysilazane material by replacing nitrogen and hydrogen atoms with oxygen atoms to form the layer into an oxygen rich material, i.e., a silicon oxide, and primarily silicon dioxide (SiO₂). The acid containing solution includes phosphoric acid, sulfuric acid, H₂SO₄ added with O₃ (SOM), H₂SO₄ added with H₂O₂ (SPM), H₃PO₄ added with O₃, or H₃PO₄ added with H₂O₂. The acid containing solution is heated to be about 100° C.—300° C. Preferably, the acid containing solution is heated to be about 150° C.—250° C. It is noted that since the acid containing solution contains acid in water, it can be heated to be more than 100° C. The mega-sonic waves have an output power ranging from about 10 watt to 2000 watt. The process time is several ten minutes or more (till the entire silicon-containing polymer layer 218 is transformed to silicon oxide).

Referring to FIG. 2E, after formation, the silicon oxide layer 220 can be planarized by a CMP, etch back, and the like process to complete the trench isolation structure 222 by removing a portion of the silicon oxide layer 220 filled into the trench 214 to be level with the substrate 202. A gate or other structure can then be fabricated according to known techniques. Thus, an exemplary shallow trench isolation structure 222 depicted in FIG. 2E, includes substrate 202, first pad layer 204, second pad layer 206, trench 214 optional silicon nitride liner layer 216 and silicon oxide layer 220.

The method of polysilazane oxidation of an embodiment of the invention has advantages as follows. First, the method of polysilazane oxidation uses a process temperature which is lower than conventional methods to completely convert polysilazane to silicon oxide. Second, since the method of polysilazane oxidation does not need high temperatures as conventional techniques, thickness of the silicon nitride liner layer on sidewalls and the bottom of the trench can be reduced or no silicon nitride liner layer is required.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of oxidizing polysilazane, comprising:
providing a substrate, comprising a trench;
forming a polysilazane layer in the trench; and
treating the polysilazane layer in an acid containing solution applied with mega-sonic waves to oxidize the polysilazane layer.

2. The method of oxidizing polysilazane as claimed in claim 1, wherein the acid containing solution comprises phosphoric acid, sulfuric acid, H₂SO₄ added with O₃ (SOM), H₂SO₄ added with H₂O₂ (SPM), H₃PO₄ added with O₃, or H₃PO₄ added with H₂O₂.

3. The method of oxidizing polysilazane as claimed in claim 1, wherein the steps of treating the polysilazane layer in the acid containing solution is performed at a temperature of between 100° C. to 300° C.

4. The method of oxidizing polysilazane as claimed in claim 1, wherein the steps of treating the polysilazane layer in the acid containing solution is performed at a temperature of between 150° C. to 250° C.

5. The method of oxidizing polysilazane as claimed in claim 1, wherein mega-sonic waves have an output power ranging from about 10 watt to 2000 watt.

6. The method of oxidizing polysilazane as claimed in claim 1, further comprising forming a silicon nitride liner layer on a sidewall and a bottom surface of the trench.

7. The method of oxidizing polysilazane as claimed in claim 6, wherein the silicon nitride liner layer has a thickness of between 5 nm and 10 nm.

8. The method of oxidizing polysilazane as claimed in claim 1, wherein polysilazane layer directly contacts the substrate with no liner layer therebetween.

9. The method of oxidizing polysilazane as claimed in claim 1, wherein the step of forming the polysilazane layer is performed by spin coating.

10. A method of forming a trench isolation structure, comprising:
providing a substrate;
forming a trench in the substrate;
forming a polysilazane layer in the trench;
treating the polysilazane layer in an acid containing solution applied with mega-sonic waves at a temperature of between 100° C. to 300° C. to convert the polysilazane layer into a silicon oxide layer, wherein the acid containing solution comprises phosphoric acid, sulfuric acid, H₂SO₄ added with O₃ (SOM), H₂SO₄ added with H₂O₂ (SPM), H₃PO₄ added with O₃, or H₃PO₄ added with H₂O₂; and
removing the silicon oxide layer outside of the trench.

11. The method of forming a trench isolation structure as claimed in claim 10, wherein the mega-sonic waves have an output power ranging from about 10 watt to 2000 watt.

12. The method of forming a trench isolation structure as claimed in claim 10, further comprising forming a silicon nitride liner layer on a sidewall and a bottom surface of the trench.

13. The method of forming a trench isolation structure as claimed in claim 10, wherein the steps of treating the polysilazane layer in the acid containing solution is performed at a temperature of between 150° C. to 250° C.

14. The method of forming a trench isolation structure as claimed in claim 10, wherein the silicon nitride liner layer has a thickness of between 5 nm and 10 nm.

15. The method of forming a trench isolation structure as claimed in claim 10, wherein the polysilazane layer directly contacts the substrate with no liner layer therebetween.

16. The method of forming a trench isolation structure as claimed in claim 10, wherein the step of forming the polysilazane layer is performed by spin coating.

17. The method of forming a trench isolation structure as claimed in claim 10, wherein the step of forming the trench comprises:
forming a first pad layer on the substrate;
forming a second pad layer on the first pad layer;
patterning the first pad layer and the second pad layer; and
etching the substrate to form the trench.

18. The method of forming a trench isolation structure as claimed in claim 17, wherein the first pad layer is made of silicon oxide and the second pad layer is made of silicon nitride.
